(19) United States
(12) Patent Application Publication
(10) Pub. No.: US 2026/0225170 A1
(43) Pub. Date: Aug. 6, 2026

(54) SUBSTRATE PROCESSING DEVICE INCLUDING LIGHT SOURCE

(71) Applicant: SAMSUNG ELECTRONICS CO., LTD., Suwon-si (KR)

(72) Inventors: Donghoon KWON, Suwon-si (KR); Boun YOON, Suwon-si (KR)

(73) Assignee: SAMSUNG ELECTRONICS CO., LTD., Suwon-si (KR)

(21) Appl. No.: 19/310,159

(22) Filed: Aug. 26, 2025

(30) Foreign Application Priority Data
Feb. 5, 2025 (KR) 10-2025-0014574

(51) Int. Cl. B23H 7/38; B23H 3/04; B23H 3/08

(52) U.S. Cl. CPC B23H 7/38; B23H 3/04; B23H 3/08

(57) ABSTRACT

Provided is a substrate processing device including: a lower electrode; a reaction chamber on the lower electrode; an electrolyte solution in the reaction chamber; and a planarization unit in contact with the electrolyte solution, wherein the planarization unit includes: a light source in the reaction chamber; and an electrode in contact with the light source, and wherein the electrolyte solution includes a photosensitizer and a photo-initiator.

### CROSS-REFERENCE TO RELATED APPLICATION

This application is based on and claims priority to Korean Patent Application No. 10-2025-0014574, filed on Feb. 5, 2025, in the Korean Intellectual Property Office, the entire contents of which are hereby incorporated by reference.

### BACKGROUND

The present disclosure relates to a substrate processing device, and in particular, to a substrate processing device including an electrode and a light source unit, which are used to planarize a top surface of a substrate in a reaction chamber.

The fabrication of a semiconductor device may be performed through several processes. For example, the fabrication of a semiconductor may include performing a photolithography process, an etching process, and a deposition process on a substrate. It is necessary to planarize the surface of the substrate before each process. For this, a planarization process may be performed on the substrate. The planarization process may be performed by various methods. An electrochemical planarization process may be used for the planarization of the substrate. For example, an Electrochemical Copper Planarization (ECP) process may be used for the planarization of the substrate.

### SUMMARY

Provided is a substrate processing device including a light source unit, which is used to expedite a photocatalyst reaction and increase a planarization rate in a substrate planarization process using an electrochemical method.

Further provided is a substrate processing device, which is configured to suppress light diffusion and expedite a photoreaction at a desired region, thereby increasing the process efficiency in the substrate planarization process.

According to an aspect of the disclosure, a substrate processing device includes: a lower electrode; a reaction chamber on the lower electrode; an electrolyte solution in the reaction chamber; and a planarization unit in contact with the electrolyte solution, wherein the planarization unit includes: a light source in the reaction chamber; and an electrode in contact with the light source, and wherein the electrolyte solution includes a photosensitizer and a photo-initiator.

According to an aspect of the disclosure, a substrate processing device includes: a lower electrode; a reaction chamber on the lower electrode; an electrolyte solution in the reaction chamber; and a planarization unit in contact with the electrolyte solution, wherein the planarization unit includes: a light source in a center region of the planarization unit, and an electrode enclosing the light source.

According to an aspect of the disclosure, a substrate processing device includes: a lower electrode; a reaction chamber on the lower electrode; a substrate connected to the lower electrode; an electrolyte solution in the reaction chamber; an adhesion member connected to an upper portion of the reaction chamber; an electrode connected to the adhesion member; and a light source connected to the electrode, wherein the electrolyte solution includes a photosensitizer and a photo-initiator.

### BRIEF DESCRIPTION OF DRAWINGS

The above and other aspects and features of certain embodiments of the present disclosure will be more apparent from the following description taken in conjunction with the accompanying drawings, in which:

FIG. 1 is a cross-sectional view illustrating a substrate processing device according to an embodiment of the disclosure;

FIG. 2 is a plan view illustrating a planarization unit of the substrate processing device of FIG. 1;

FIG. 3 is a cross-sectional view illustrating a substrate processing device according to an embodiment of the disclosure;

FIG. 4 is a cross-sectional view illustrating a substrate processing device according to an embodiment of the disclosure;

FIG. 5 is a plan view illustrating a planarization unit of the substrate processing device of FIGS. 3 and 4;

FIG. 6 is a cross-sectional view illustrating a substrate processing device according to an embodiment of the disclosure;

FIG. 7 is a plan view illustrating a planarization unit of the substrate processing device of FIG. 6;

FIG. 8 is a cross-sectional view illustrating a substrate processing device according to an embodiment of the disclosure;

FIG. 9 is a cross-sectional view illustrating a substrate processing device according to an embodiment of the disclosure;

FIG. 10 is a plan view illustrating a planarization unit of the substrate processing device of FIGS. 8 and 9;

FIG. 11 is a cross-sectional view illustrating a substrate processing device according to an embodiment of the disclosure;

FIG. 12 is a plan view illustrating a planarization unit of the substrate processing device of FIG. 11;

FIG. 13 is a cross-sectional view illustrating a substrate processing device according to an embodiment of the disclosure;

FIG. 14 is a plan view illustrating a planarization unit of the substrate processing device of FIG. 13;

FIG. 15 is a cross-sectional view illustrating a substrate processing device according to an embodiment of the disclosure; and

FIG. 16 is a plan view illustrating a planarization unit of the substrate processing device of FIG. 15.

### DETAILED DESCRIPTION

One or more example embodiments of the present disclosure will now be described more fully with reference to the accompanying drawings, in which one or more example embodiments are shown. Like reference numerals in the drawings denote like elements, and thus their description will be omitted.

In the present application, the reference numbers D1, D2, and D3 will be used to denote a first direction, a second direction, and a third direction, respectively, which are not parallel to each other. The third direction D3 may be referred to as an upward direction, and the opposite direction of the third direction D3 may be referred to as a downward direction. In addition, each of the first and second directions D1 and D2 may be referred to as a horizontal direction.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

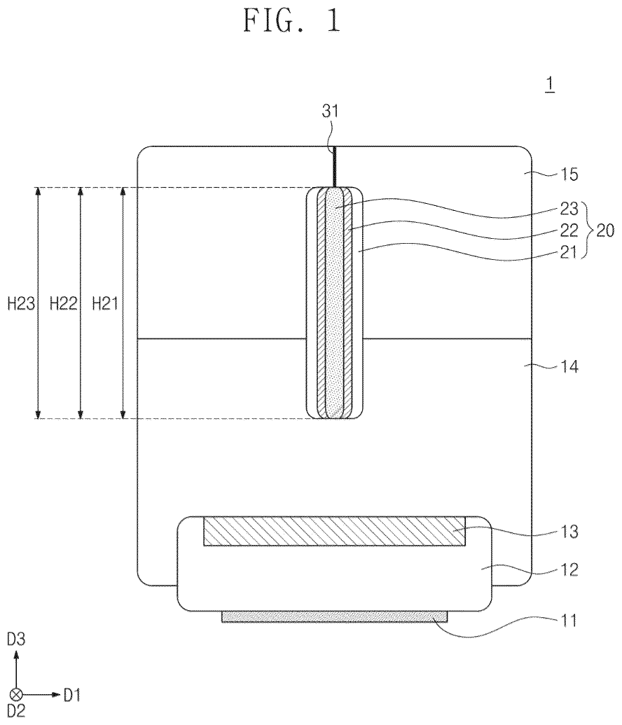

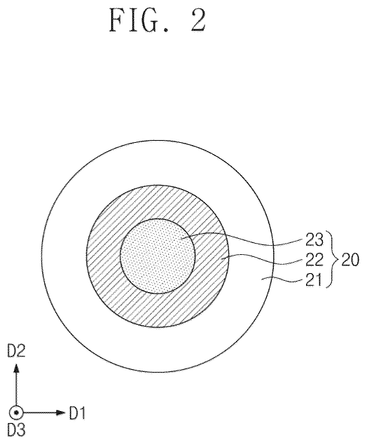

FIG. 1 is a cross-sectional view illustrating a substrate processing device according to an embodiment of the disclosure. FIG. 2 is a plan view illustrating a planarization unit of the substrate processing device of FIG. 1.

Referring to FIGS. 1 and 2, a substrate processing device 1 may include a lower electrode 11, a substrate 12 on the lower electrode 11, a pattern 13 in the substrate 12, a reaction chamber 15 on the lower electrode 11, an electrolyte solution 14 in the reaction chamber 15, an adhesion member 31 connected to an upper portion of the reaction chamber 15, and a planarization unit 20 connected to the adhesion member 31.

The lower electrode 11 may include a conductive material. The lower electrode 11 may support the substrate 12. More specifically, the substrate 12 may be placed on a top surface of the lower electrode 11. The substrate 12 on the top surface of the lower electrode 11 may rotate, when viewed in a plan view. In the present specification, the term “when viewed in a plan view” may refer to a top-down perspective, as shown in FIG. 2. The lower electrode 11 may be connected to a power source and may be used to apply a voltage to the substrate 12.

The substrate 12 may be provided on the lower electrode 11. The substrate 12 may include a silicon wafer, but the disclosure is not limited to this example. The substrate processing device 1 may be configured to place an object, to which a planarization process will be performed, in place of the substrate 12.

The pattern 13 may be provided in an upper portion of the substrate 12. The pattern 13 may include a non-uniform top surface. The non-uniform top surface of the pattern 13 may be planarized by the substrate processing device 1. The pattern 13 may include, for example, a conductive material. In an embodiment, the pattern 13 may include a non-uniform copper pattern. The pattern 13 may be in contact with the electrolyte solution 14. A top surface of the pattern 13 may be exposed to the electrolyte solution 14. When viewed in a plan view, the size of the substrate 12 may be equal to or larger than the size of the pattern 13, but the disclosure is not limited to this example.

The reaction chamber 15 may be disposed on the lower electrode 11. The reaction chamber 15 may be provided to have an inner space, which is used to treat a substrate. A lower portion of the reaction chamber 15 may be filled with the electrolyte solution 14, but the upper portion of the reaction chamber 15 may not be filled with the electrolyte solution 14. The upper portion of the reaction chamber 15 may be an empty space.

The electrolyte solution 14 in the reaction chamber 15 may include a viscous electrolyte. In an embodiment, the electrolyte solution 14 in the reaction chamber 15 may include at least one of a photosensitizer or a photo-initiator.

The electrolyte solution 14 in the reaction chamber 15 may include oxygen dissolved therein. The electrolyte solution 14 may further include other by-products. The dissolved oxygen may generate hydrogen peroxide (H₂O₂) through a reduction process. The hydrogen peroxide (H₂O₂) may be used to dissolve the non-uniform top surface of the pattern 13.

The photosensitizer may include at least one of melanin, chlorophyll, hemoglobin, beta-carotene, or carbon black.

The photo-initiator may include at least one of benzoyl peroxide, 2,2-dimethoxy-2-phenylacetophenone, or 2,2′-azobis[2-methyl-n-(2-hydroxylethyl) propionamide].

In an embodiment, the electrolyte solution 14 may include a photocatalyst. If light provided from a light source 23 is visible light, the photocatalyst may be one of Au/TiO₂, TiO₂/SeO₂, or TiO₂/SiO₂. If the light is ultraviolet light, photocatalyst may be one of TiO₂, ZnO, ZrO₂, CdSe, WO₃/TiO₂, and Al₂O₃/ZrO₂. Highly oxidative hydroxyl radicals (OH radicals) may be generated through hydrolysis induced by the photocatalyst reaction. The planarization rate of the pattern 13 may be adjusted through the oxidation reaction of the hydroxy radical.

The adhesion member 31 may be disposed in the upper portion of the reaction chamber 15. The adhesion member 31 may be connected to a top surface of the reaction chamber 15. The planarization unit 20 may be connected to the top surface of the reaction chamber 15 by the adhesion member 31. The adhesion member 31 and the electrolyte solution 14 may be spaced apart from each other.

The planarization unit 20 may be connected to the adhesion member 31. A portion of the planarization unit 20 may be disposed in the electrolyte solution 14, and a portion of the planarization unit 20 may be exposed. The planarization unit 20 may be connected to and fastened to the upper portion of the reaction chamber 15 by the adhesion member 31.

The planarization unit 20 may include the light source 23, which is provided to penetrate the same, an electrode 22 at least partially enclosing or surrounding a length of the light source 23, and a protection housing 21 at least partially enclosing or surrounding a length of the electrode 22.

The light source 23 may have a cylindrical shape. When viewed in a plan view, the light source 23 may have a circular cross-section. A bottom surface of the light source 23 may be exposed and may be configured to provide light to the top surface of the pattern 13. The light source 23 may expedite the photocatalyst reaction, and the non-uniform top surface of the pattern 13 may be partially dissolved by the electrolyte solution 14 through the photocatalyst reaction. As a result of the photocatalyst reaction, the non-uniform top surface of the pattern 13 may be planarized.

The electrode 22 may be provided to at least partially enclose the light source 23. In an embodiment, the electrode 22 may have a ring shape enclosing the light source 23. The electrode 22 may include a conductive material. The electrode 22 may generate an electric field in the electrolyte solution 14. In an embodiment, the electrode 22 may be used to provide free electrons in the electrolyte solution 14.

The protection housing 21 may be provided to at least partially enclose the electrode 22. In an embodiment, the protection housing 21 may have a ring shape enclosing the electrode 22. The protection housing 21 may be configured to protect the electrode 22 and prevent the electrode 22 from being oxidized or corroded, thereby increasing the lifetime of the electrode 22.

A height H23 of the light source 23 may be substantially equal to a height H22 of the electrode 22. The height H23 of the light source 23 may be substantially equal to a height H21 of the protection housing 21. The height H21 of the electrode 22 may be substantially equal to the height H21 of the protection housing 21.

In the present specification, the term “height” may mean a vertical length of an object in the third direction D3. In the present specification, the expression “substantially equal to” or “substantially the same as” may mean that the difference is smaller than an error margin (e.g., From −5% to +5%).

According to an embodiment of the disclosure, the substrate processing device 1 may be configured to include the light source 23 that is placed in the electrode 22. In this case, it may be possible to expedite the oxidation reaction of the pattern 13 in a process of planarizing the top surface of the pattern 13 through the photocatalyst reaction.

In addition the substrate processing device 1 may include the photosensitizer and the photo-initiator. Due to the photosensitizer, a photoreaction may occur in a desired region, without undesired light diffusion. For example, it may be possible to irradiate light onto protruding portions of the pattern 13 with a nonuniform profile, and this may make it possible to increase the efficiency of the planarization process. The photo-initiator may expedite the oxidation reaction in the protruding portions of the pattern 13. In this case, the efficiency of the planarization reaction may be increased.

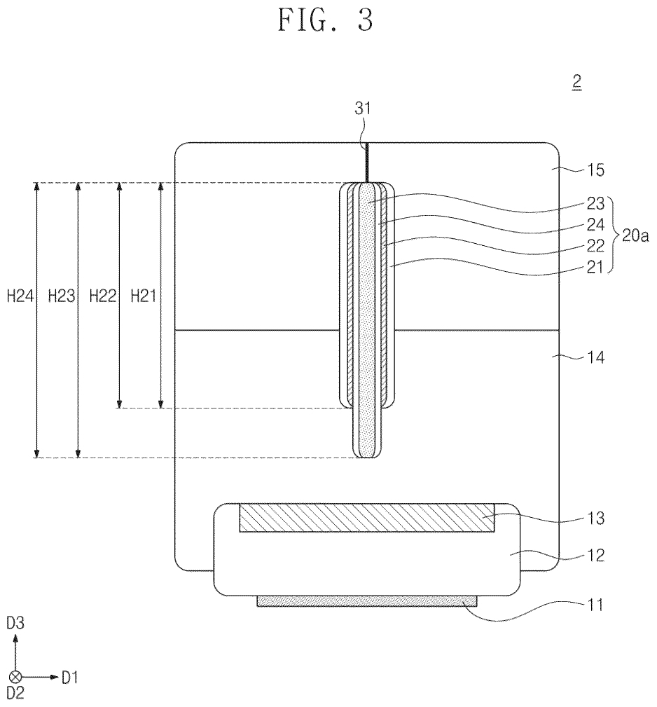

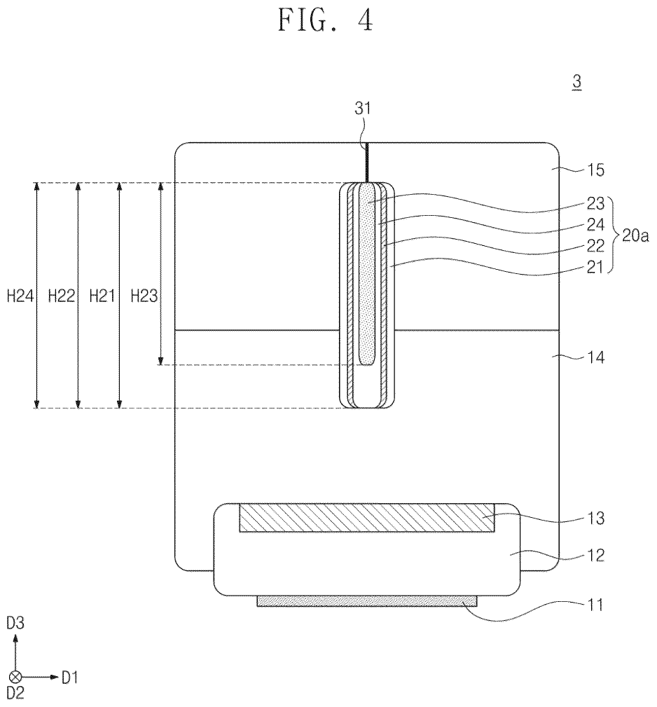

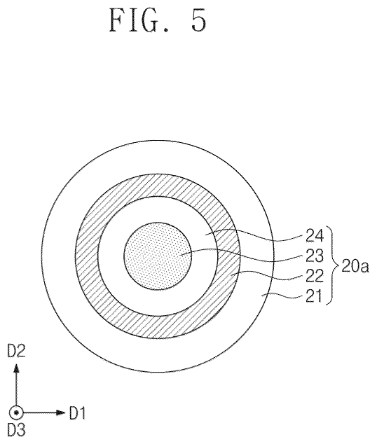

FIG. 3 is a cross-sectional view illustrating a substrate processing device according to an embodiment of the disclosure. FIG. 5 is a plan view illustrating a planarization unit of the substrate processing device of FIGS. 3 and 4. To avoid duplicative descriptions, previously described elements may be identified by the same reference number used above without repeating an overlapping description thereof.

Referring to FIGS. 3 and 5, a substrate processing device 2 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, and a planarization unit 20a connected to the adhesion member 31.

The planarization unit 20a may include the light source 23, which is provided to penetrate the same, a cover member 24 at least partially enclosing the light source 23, the electrode 22 at least partially enclosing the cover member 24, and the protection housing 21 at least partially enclosing the electrode 22. The cover member 24 may be interposed between the light source 23 and the electrode 22.

Referring to FIG. 5, the light source 23 may have a circular section, when viewed in a plan view. In an embodiment, the cover member 24 may have a ring shape enclosing a length of the light source 23 while leaving a bottom surface of the light source 23 exposed. In an embodiment, the electrode 22 may have a ring shape enclosing the cover member 24. In an embodiment, the protection housing 21 may have a ring shape enclosing the electrode 22.

The cover member 24 may be disposed between the light source 23 and the electrode 22. The electrode 22 may be disposed between the cover member 24 and the protection housing 21. The light source 23 and the cover member 24 may have a relatively protruding shape. In other words, a bottom surface of the light source 23 and a bottom surface of the cover member 24 may be placed at a level that is lower than bottom surfaces of the electrode 22 and the protection housing 21. Here, the term “level” may be defined as a distance from a top surface of the substrate 12 measured in the third direction D3. The expression “the level is low” may mean that the distance from the top surface of the substrate 12 in the third direction D3 is small.

The height H23 of the light source 23 may be substantially equal to a height H24 of the cover member 24. The height H22 of the electrode 22 may be substantially equal to the height H21 of the protection housing 21. The height H23 of the light source 23 may be greater than the height H22 of the electrode 22. The height H23 of the light source 23 may be greater than the height H21 of the protection housing 21. The height H24 of the cover member 24 may be greater than the height H22 of the electrode 22. The height H24 of the cover member 24 may be greater than the height H21 of the protection housing 21.

Since the light source 23 protrudes relative to the electrode 22, light from the light source 23 may be emitted at various angles. Since the cover member 24 is provided to enclose a length of the light source 23 and have a protruding shape, the light source 23 may be protected by the cover member 24.

FIG. 4 is a cross-sectional view illustrating a substrate processing device according to an embodiment of the disclosure. FIG. 5 is a plan view illustrating a planarization unit of the substrate processing device of FIGS. 3 and 4. For concise description, a previously described element may be identified by the same reference number without repeating an overlapping description thereof.

Referring to FIGS. 4 and 5, a substrate processing device 3 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, and the planarization unit 20a connected to the adhesion member 31.

The planarization unit 20a may include the light source 23, which is provided in its center region, the cover member 24 enclosing side and bottom surfaces of the light source 23, the electrode 22 enclosing the cover member 24, and the protection housing 21 enclosing the electrode 22.

The light source 23 may have a recessed shape. The bottom surface of the light source 23 may be covered with the cover member 24. The bottom surface of the light source 23 may be located at a level that is higher than bottom surfaces of the cover member 24, the electrode 22, and the protection housing 21. The expression “the level is high” may mean that a distance from the top surface of the substrate 12 in the third direction D3 is large.

The height H24 of the cover member 24 may be substantially equal to the height H22 of the electrode 22. The height H22 of the electrode 22 may be substantially equal to the height H21 of the protection housing 21. The height H24 of the cover member 24 may be substantially equal to the height H21 of the protection housing 21. The height H23 of the light source 23 may be smaller than the height H24 of the cover member 24. The height H23 of the light source 23 may be smaller than the height H21 of the protection housing 21. The height H23 of the light source 23 may be smaller than the height H22 of the electrode 22.

Since the light source 23 is recessed relative to the electrode 22, the light source 23 may provide light with increased intensity. Since the light source 23 encloses the cover member 24, the light source 23 may be protected by the cover member 24.

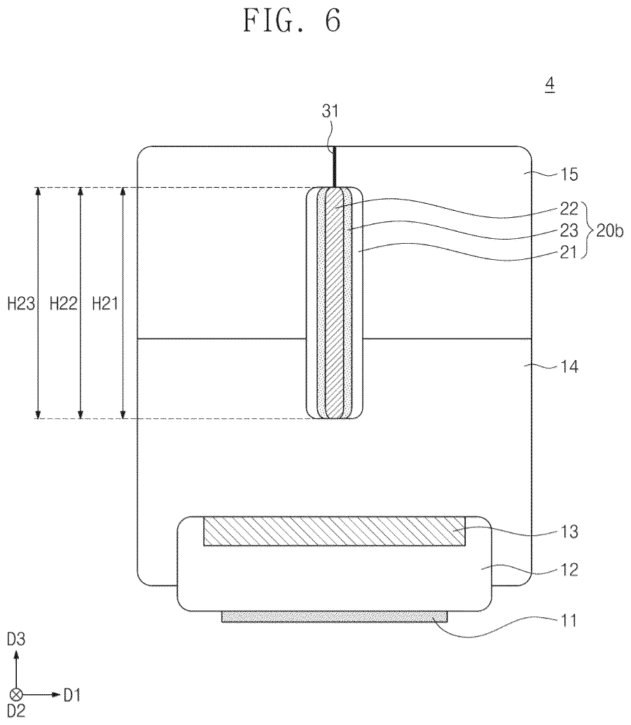

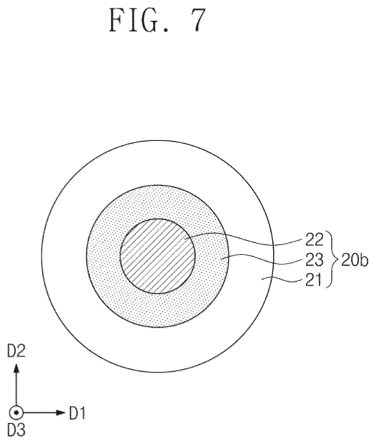

FIG. 6 is a cross-sectional view illustrating a substrate processing device according to an embodiment of the disclosure. FIG. 7 is a plan view illustrating a planarization unit of the substrate processing device of FIG. 6. To avoid duplicative descriptions, previously described elements may be identified by the same reference numbers used above without repeating overlapping descriptions thereof.

Referring to FIGS. 6 and 7, a substrate processing device 4 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, and a planarization unit 20b connected to the adhesion member 31.

The planarization unit 20b may include the electrode 22, which is provided in its center region, the light source 23 at least partially enclosing the electrode 22, and the protection housing 21 at least partially enclosing the light source 23.

The electrode 22 may have a cylindrical rod shape. The electrode 22 may have a circular section, when viewed in a plan view. In an embodiment, the light source 23 may have a ring shape enclosing the electrode 22. In an embodiment, the protection housing 21 may have a ring shape enclosing the light source 23.

The height H22 of the electrode 22 may be substantially equal to the height H23 of the light source 23. The height H22 of the electrode 22 may be substantially equal to the height H21 of the protection housing 21. The height H23 of the light source 23 may be substantially equal to the height H21 of the protection housing 21.

In an embodiment where the light source 23 is provided in the form of a ring enclosing the electrode 22, the light source 23 may be used to illuminate a broader space.

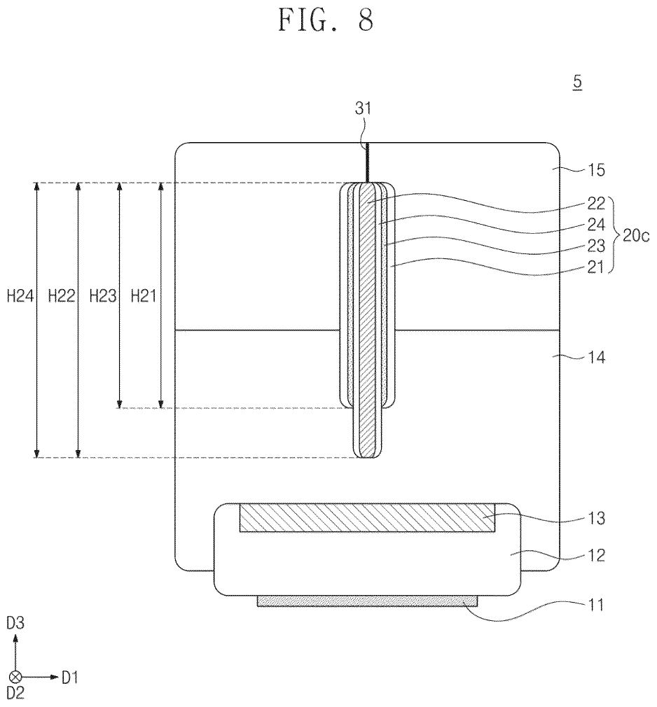

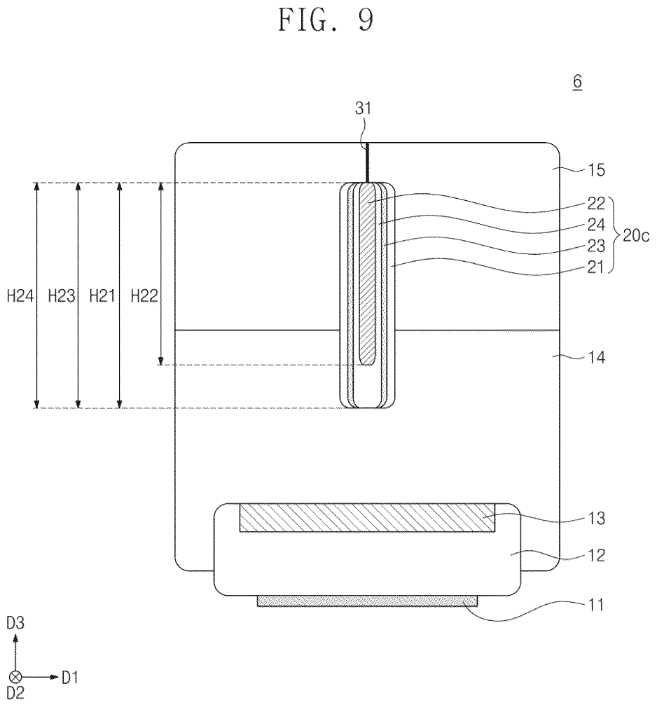

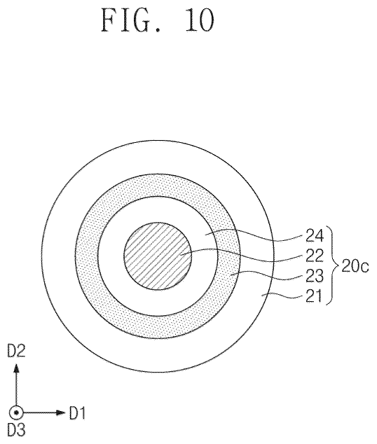

FIG. 8 is a cross-sectional view illustrating a substrate processing device according to an embodiment of the disclosure. FIG. 10 is a plan view illustrating a planarization unit of the substrate processing device of FIGS. 8 and 9. To avoid duplicative descriptions, previously described elements may be identified by the same reference numbers used above without repeating overlapping descriptions thereof.

Referring to FIGS. 8 and 10, a substrate processing device 5 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, and a planarization unit 20c connected to the adhesion member 31.

The planarization unit 20c may include the electrode 22, which is provided to penetrate the planarization unit 20c, the cover member 24 at least partially enclosing the electrode 22, the light source 23 at least partially enclosing the cover member 24, and the protection housing 21 at least partially enclosing the light source 23.

In an embodiment, the electrode 22 and the cover member 24 may have a relatively protruding shape. In other words, a bottom surface of the electrode 22 and the bottom surface of the cover member 24 may be located at a level that is lower than bottom surfaces of the light source 23 and the protection housing 21.

The height H22 of the electrode 22 may be substantially equal to the height H24 of the cover member 24. The height H23 of the light source 23 may be substantially equal to the height H21 of the protection housing 21. The height H23 of the light source 23 may be less than the height H22 of the electrode 22. The height H23 of the light source 23 may be less than the height H21 of the cover member 24. The height H21 of the protection housing 21 may be less than the height H22 of the electrode 22. The height H21 of the protection housing 21 may be less than the height H24 of the cover member 24.

Since the electrode 22 protrudes relative to the light source 23, free electrons from the electrode 22 may be emitted at various angles. Since the cover member 24 is provided to enclose the electrode 22 and have a protruding shape, the electrode 22 may be protected by the cover member 24.

FIG. 9 is a cross-sectional view illustrating a substrate processing device according to an embodiment of the disclosure. FIG. 10 is a plan view illustrating a planarization unit of the substrate processing device of FIGS. 8 and 9. To avoid duplicative descriptions, previously described elements may be identified by the same reference numbers used above without repeating overlapping descriptions thereof.

Referring to FIGS. 9 and 10, a substrate processing device 6 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, and the planarization unit 20c connected to the adhesion member 31.

The planarization unit 20c may include the electrode 22, which is provided to penetrate the planarization unit 20c, the cover member 24 at least partially enclosing side and bottom surfaces of the electrode 22, the light source 23 at least partially enclosing the cover member 24, and the protection housing 21 at least partially enclosing the light source 23.

In an embodiment, the electrode 22 may have a recessed shape, and the bottom surface of the electrode 22 may be covered with the cover member 24. The bottom surface of the electrode 22 may be located at a level that is higher than bottom surfaces of the cover member 24, the light source 23, and the protection housing 21.

The height H24 of the cover member 24 may be substantially equal to the height H23 of the light source 23. The height H23 of the light source 23 may be substantially equal to the height H21 of the protection housing 21. The height H24 of the cover member 24 may be substantially equal to the height H21 of the protection housing 21. The height H22 of the electrode 22 may be less than the height H24 of the cover member 24. The height H22 of the electrode 22 may be less than the height H21 of the protection housing 21. The height H23 of the light source 23 may be greater than the height H22 of the electrode 22.

Since the electrode 22 is recessed relative to the light source 23, the electrode 22 may be used to generate free electrons at a higher density. Since the electrode 22 is enclosed by the cover member 24, the electrode 22 may be protected. For example, it may be possible to prevent or suppress corrosion and damage to the electrode.

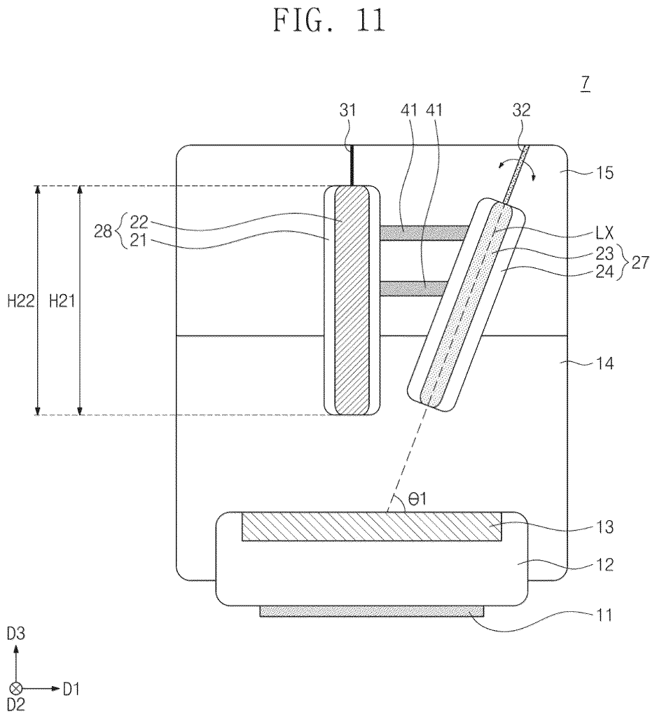

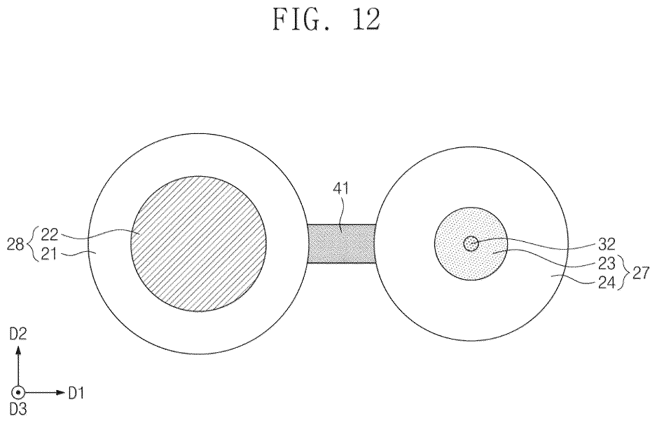

FIG. 11 is a cross-sectional view illustrating a substrate processing device according to an embodiment of the disclosure. FIG. 12 is a plan view illustrating a planarization unit of the substrate processing device of FIG. 11. To avoid duplicative descriptions, previously described elements may be identified by the same reference numbers used above without repeating overlapping descriptions thereof.

Referring to FIGS. 11 and 12, a substrate processing device 7 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, an electrode structure 28 connected to the adhesion member 31, and a light-emitting structure 27 connected to the electrode structure 28. The substrate processing device 7 may further include a rotation member 32 fastening and rotating the light-emitting structure 27.

The electrode structure 28 and the light-emitting structure 27 may be spaced apart from each other. The electrode structure 28 and the light-emitting structure 27, which are spaced apart from each other, may be connected to a connection member 41. The connection member 41 may connect a side surface of the electrode structure 28 to a side surface of the light-emitting structure 27. In an embodiment, a plurality of connection members 41 may be provided. The connection member 41 may include an insulating material. The protection housing 21 and the cover member 24 may be connected to the connection member 41.

The electrode structure 28 may include the electrode 22 and the protection housing 21 enclosing the electrode 22. The electrode 22 may be provided to be perpendicular to the top surface of the substrate 12. The electrode 22 may have a shape extending in the third direction D3. The electrode 22 may be disposed in a center region of the electrode structure 28. The electrode 22 may have a cylindrical rod shape. The protection housing 21 may have a ring shape at least partially enclosing the electrode 22.

The light-emitting structure 27 may include the light source 23 and the cover member 24 at least partially enclosing the light source 23. The light source 23 may be disposed at the center of the light-emitting structure 27. The light source 23 may have a cylindrical rod shape. In an embodiment, the cover member 24 may have a ring shape enclosing the light source 23.

A longitudinal axis of the light-emitting structure 27, which is placed to be parallel to the length direction of the light source 23, may be defined as a longitudinal axis LX. The rotation member 32 may be connected to the axis LX, which is placed to be parallel to the length direction of the light source 23. The rotation member 32 may rotate in a clockwise or counter-clockwise direction. Due to the rotation of the rotation member 32, the light source 23 and the light-emitting structure 27 may also rotate. When viewed in a plan view, the rotation member 32 may be overlapped with the center of the light-emitting structure 27. The height H22 of the electrode 22 may be equal to the height H21 of the protection housing 21.

The light source 23 and the top surface of the substrate 12 may be provided to form a first angle θ1. More specifically, the longitudinal axis LX of the light source 23 and the top surface of the substrate 12 may form the first angle θ1. The first angle θ1 may be an acute angle. Since the first angle θ1 is the acute angle, the supplementary angle of the first angle θ1 may be an obtuse angle. That is, an angle between the length axis LX of the light source 23 and the top surface of the substrate 12 may be obtuse, depending on a measuring direction. The first angle θ1 between the longitudinal axis LX of the light source 23 and the top surface of the substrate 12 may be an acute angle, and the supplementary angle of the first angle θ1, which is formed between the longitudinal axis LX of the light source 23 and the top surface of the substrate 12, may be an obtuse angle. The first angle θ1 may not be the right angle.

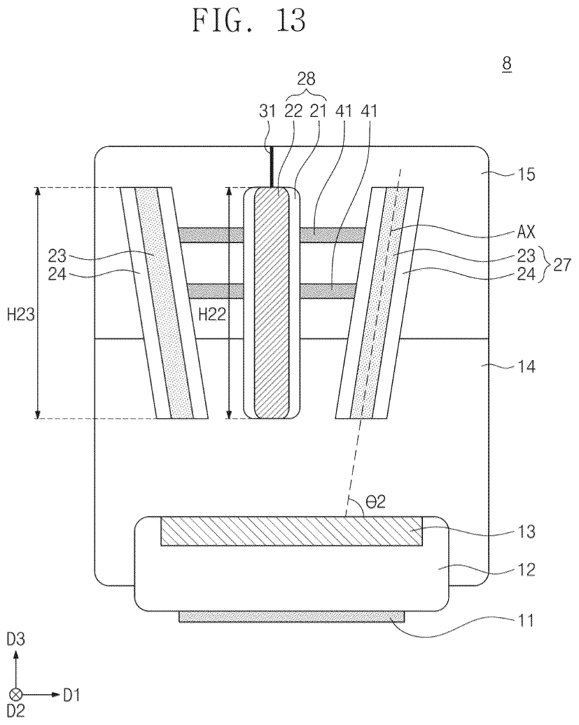

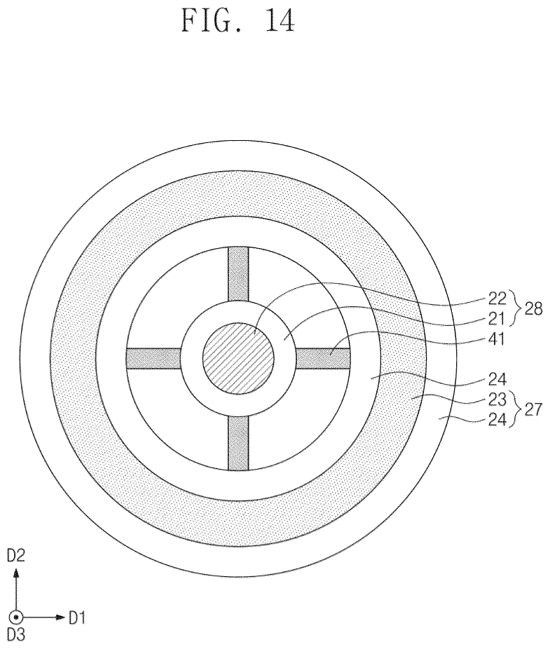

FIG. 13 is a cross-sectional view illustrating a substrate processing device according to an embodiment of the disclosure. FIG. 14 is a plan view illustrating a planarization unit of the substrate processing device of FIG. 13. To avoid duplicative descriptions, previously described elements may be identified by the same reference numbers used above without repeating overlapping descriptions thereof.

Referring to FIGS. 13 and 14, a substrate processing device 8 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, the electrode structure 28 connected to the adhesion member 31, and the light-emitting structure 27 connected to the electrode structure 28.

The electrode structure 28 and the light-emitting structure 27 may be spaced apart from each other. The electrode structure 28 and the light-emitting structure 27, which are spaced apart from each other, may be connected to the connection member 41. The connection member 41 may connect a side surface of the electrode structure 28 to a side surface of the light-emitting structure 27. In an embodiment, a plurality of connection members 41 may be provided. The protection housing 21 and the cover member 24 may be connected to the connection member 41.

When viewed in a plan view, the electrode structure 28 may have a cylindrical shape. More specifically, the electrode structure 28 may be provided to include the electrode 22, which is placed in a center region of the electrode structure 28, and the protection housing 21, which is placed to at least partially enclose the electrode 22, and may have a cylindrical shape.

When viewed in a plan view, the light-emitting structure 27 may have a ring shape surrounding the electrode structure 28. However, when viewed in cross-section, the light-emitting structure 27 may have a conical shape (see, e.g., FIG. 13). The light-emitting structure 27 may include the light source 23, which is provided in the ring shape, and the cover member 24, which is provided to at least partially enclose outer and inner surfaces of the light source 23. The cover member 24 may be composed of two rings, which are respectively provided to at least partially enclose the outer and inner surfaces of the light source 23. In an embodiment, the cover member 24, which is provided to enclose the inner surface of the light source 23, may be connected to the electrode structure 28 by the connection member 41. In an embodiment, the cover member 24, which is provided to enclose the inner surface of the light source 23, may be connected to the protection housing 21.

The electrode structure 28 may be placed in a hollow center region of the ring shape of the light-emitting structure 27. The light-emitting structure 27 and the electrode structure 28 may be arranged in a concentric manner.

An inclination axis AX of the light source 23 and the top surface of the substrate 12 may form a second angle θ2. For the purposes of this disclosure, the longitudinal axis LX and the inclination axis AX are generally interchangeable with regard to determination of the angles θ1 and θ2. In the substrate processing device 8, the inclination axis AX of the light source 23 may be defined as an axis passing through the centers of the top and bottom surfaces of the light source 23, when viewed in cross-section. The second angle θ2 may be an acute angle. Depending on a measurement direction, the second angle θ2 may be an obtuse angle. The second angle θ2 may not be the right angle.

The height H23 of the light source 23 may be substantially equal to the height H22 of the electrode 22. Since the inclination axis AX of the light source 23 and the top surface of the substrate 12 form the second angle θ2, the height H23 of the light source 23 in the third direction may be different from the length of the light source 23. The length of the light source 23 may be defined as a distance between the centers of the top and bottom surfaces of the light source 23, when viewed in cross-section. The length of the light source 23 may be longer than the length of the electrode 22.

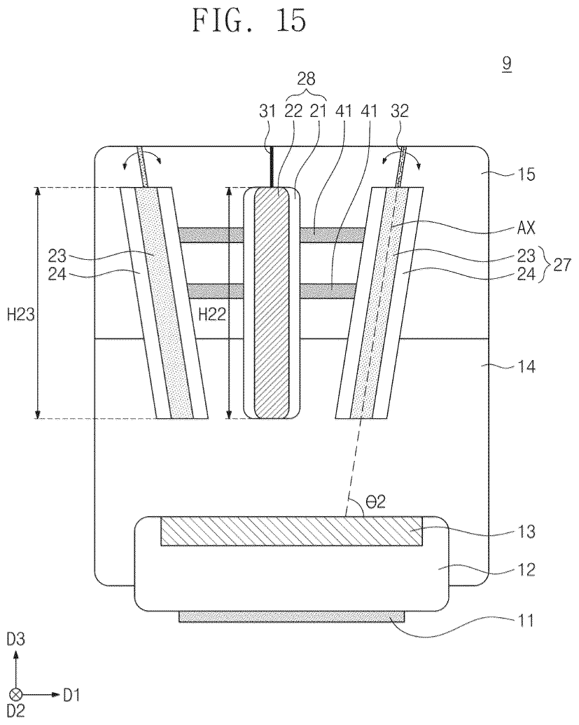

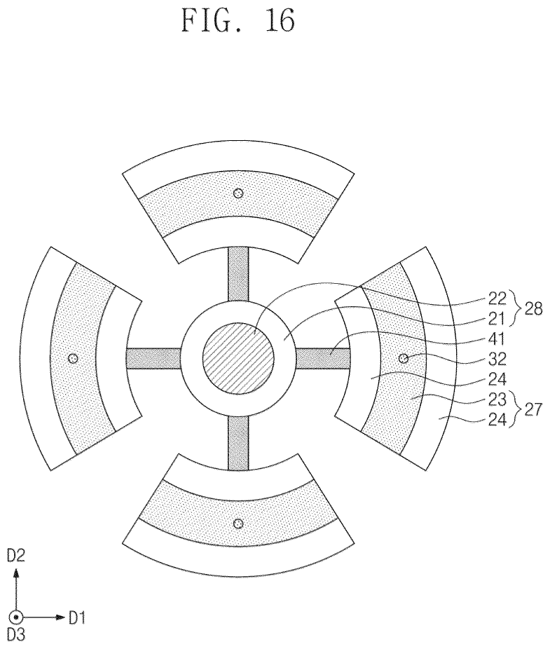

FIG. 15 is a cross-sectional view illustrating a substrate processing device according to an embodiment of the disclosure. FIG. 16 is a plan view illustrating a planarization unit of the substrate processing device of FIG. 15. To avoid duplicative descriptions, previously described elements may be identified by the same reference numbers used above without repeating overlapping descriptions thereof.

Referring to FIGS. 15 and 16, a substrate processing device 9 may include the lower electrode 11, the substrate 12 on the lower electrode 11, the pattern 13 in the substrate 12, the reaction chamber 15 on the lower electrode 11, the electrolyte solution 14 in the reaction chamber 15, the adhesion member 31 connected to the upper portion of the reaction chamber 15, the electrode structure 28 connected to the adhesion member 31, and the light-emitting structure 27 connected to the electrode structure 28.

The electrode structure 28 and the light-emitting structure 27 may be spaced apart from each other. The electrode structure 28 and the light-emitting structure 27, which are spaced apart from each other, may be connected to each other by the connection member 41. The connection member 41 may connect a side surface of the electrode structure 28 to a side surface of the light-emitting structure 27. In an embodiment, a plurality of connection members 41 may be provided. The protection housing 21 and the cover member 24 may be connected to the connection member 41. In an embodiment, a plurality of light-emitting structures 27 may be provided.

Referring back to FIG. 16, four light-emitting structures 27 may be provided to enclose the electrode structure 28, when viewed in a plan view. The four light-emitting structures 27 may be spaced apart from each other. More specifically, the four light-emitting structures 27 may be placed to form a ring-shaped (or conical shaped) structure enclosing the electrode structure 28. The four light-emitting structures 27 may be arranged in a four-quadrant circular layout. So far, the four light-emitting structures 27 have been described as enclosing the electrode structure 28, but in an embodiment, “n” light-emitting structures 27 may be arranged to enclose the electrode structure 28, where n is not equal to four. In other words, the number of the light-emitting structures 27 enclosing the electrode structure 28 is not limited to four.

Referring back to FIGS. 15 and 16, the angle of the light-emitting structures 27 may be adjusted by the rotation member 32. Similar to the inclination axis AX of FIGS. 13 and 14, the light-emitting structure 27 may have the inclination axis AX. Similar to the second angle θ2 of FIGS. 13 and 14, the light-emitting structure 27 may have the second angle θ2. The second angle θ2 may be adjusted by the rotation member 32.

The electrode structure 28 may include the electrode 22, which is placed at its center region, and the protection housing 21, which is provided to at least partially enclose the electrode 22. The light-emitting structure 27 may include the light source 23, which is place at its center region, and the cover member 24, which is provided to at least partially cover outer and inner surfaces of the light source 23.

The height H22 of the electrode 22 may be equal to the height H23 of the light source 23. Since the light source 23 and the top surface of the substrate 12 form the second angle θ2, the length of the light source 23 may be different from the height H23 of the light source 23. When viewed in cross-section, a length from the center point of the top surface of the light source 23 to the center point of the bottom surface of the light source 23 may be less than the height H23 of the light source 23.

Since the light source 23 is provided in a circle-like shape and the angle of the light source 23 can be adjusted by the rotation member 32, it may be possible to send light to a desired portion of the pattern 13. The planarization process on the pattern 13 may be more efficiently performed.

In a substrate processing device according to an embodiment of the disclosure, an electrode and a light source may be used to efficiently planarize a non-uniform top surface of a substrate.

In a substrate processing device according to an embodiment of the disclosure, an electrolyte solution in a reaction chamber may include a photosensitizer and a photo-initiator, which are used to efficiently planarize a local region of a substrate.

While one or more example embodiments of the disclosure have been particularly shown and described, it will be understood by one of ordinary skill in the art that variations in form and detail may be made therein without departing from the spirit and scope of the attached claims.

What is claimed is:

1. A substrate processing device comprising:
a lower electrode;
a reaction chamber on the lower electrode;
an electrolyte solution in the reaction chamber; and
a planarization unit in contact with the electrolyte solution,
wherein the planarization unit comprises:
a light source in the reaction chamber; and
an electrode in contact with the light source, and
wherein the electrolyte solution comprises a photosensitizer and a photo-initiator.

2. The substrate processing device of claim 1, wherein the light source is in a center region of the planarization unit, and
wherein the electrode is at least partially encloses the light source.

3. The substrate processing device of claim 1, wherein the photosensitizer comprises at least one of melanin, chlorophyll, hemoglobin, beta-carotene, or carbon black.

4. The substrate processing device of claim 1, wherein the photo-initiator comprises at least one of benzoyl peroxide, 2,2-dimethoxy-2-phenylacetophenone, or 2,2′-azobis[2-methyl-n-(2-hydroxylethyl) propionamide].

5. The substrate processing device of claim 1, wherein the planarization unit further comprises a cover member between the light source and the electrode, and
wherein a height of the light source is greater than a height of the electrode.

6. The substrate processing device of claim 1, wherein the planarization unit further comprises a protection housing at least partially enclosing the electrode, and
wherein a height of the protection housing is substantially equal to a height of the electrode.

7. The substrate processing device of claim 1, wherein the planarization unit further comprises a cover member enclosing side and bottom surfaces of the light source,
wherein a height of the light source is less than a height of the electrode, and
wherein the light source and the electrolyte solution are spaced apart.

8. The substrate processing device of claim 1, wherein the planarization unit further comprises a protection housing in contact with the light source and the electrolyte solution,
wherein the electrode is in a center region of the planarization unit, and
wherein the light source at least partially encloses the electrode.

9. The substrate processing device of claim 8, wherein the planarization unit further comprises a cover member between the electrode and the light source, and
wherein a height of each of the electrode and the cover member is greater than a height of the light source.

10. A substrate processing device comprising:
a lower electrode;
a reaction chamber on the lower electrode;
an electrolyte solution in the reaction chamber; and
a planarization unit in contact with the electrolyte solution, wherein the planarization unit comprises:
a light source in a center region of the planarization unit, and
an electrode enclosing the light source.

11. The substrate processing device of claim 10, wherein the electrolyte solution comprises a photosensitizer, and
wherein the photosensitizer comprises at least one of melanin, chlorophyll, hemoglobin, beta-carotene, or carbon black.

12. The substrate processing device of claim 10, wherein the electrolyte solution comprises a photo-initiator, and
wherein the photo-initiator comprises at least one of benzoyl peroxide, 2,2-dimethoxy-2-phenylacetophenone, or 2,2′-azobis[2-methyl-n-(2-hydroxylethyl) propionamide].

13. The substrate processing device of claim 10, wherein the planarization unit further comprises a protection housing at least partially enclosing the electrode, and
wherein a height of the protection housing is substantially equal to a height of the electrode.

14. The substrate processing device of claim 10, wherein the light source has a cylindrical rod shape, and
wherein the electrode has a ring shape.

15. The substrate processing device of claim 10, wherein the planarization unit further comprises a cover member between the light source and the electrode, and
wherein a height of the light source is greater than a height of the electrode.

16. The substrate processing device of claim 10, wherein the planarization unit further comprises a cover member enclosing side and bottom surfaces of the light source, and
wherein a height of the light source is less than a height of the electrode.

17. A substrate processing device comprising:
a lower electrode;
a reaction chamber on the lower electrode;
a substrate connected to the lower electrode;
an electrolyte solution in the reaction chamber;
an adhesion member connected to an upper portion of the reaction chamber;
an electrode connected to the adhesion member; and
a light source connected to the electrode,
wherein the electrolyte solution comprises a photosensitizer and a photo-initiator.

18. The substrate processing device of claim 17, wherein the electrode and the light source are connected to a connection member.

19. The substrate processing device of claim 18, wherein an inclination axis of the light source and a top surface of the substrate form an acute angle.

20. The substrate processing device of claim 18, wherein the electrode has a cylindrical rod shape,
wherein the light source is spaced apart from the electrode, and
wherein the light source has a ring shape at least partially enclosing the electrode.
